(19) United States
(12) Patent Application Publication
(10) Pub. No.: US 2018/0020559 A1
(43) Pub. Date: Jan. 18, 2018

(54) CASE

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTC., Osaka-shi, Osaka (JP)

(72) Inventors: Hideaki Tahara, Yokkaichi, Mie (JP); Kazuyoshi Ohara, Yokkaichi, Mie (JP); Munsoku O, Yokkaichi, Mie (JP); Arinobu Nakamura, Yokkaichi, Mie (JP)

(21) Appl. No.: 15/547,873

(22) PCT Filed: Jan. 28, 2016
(86) PCT No.: PCT/JP2016/052408

§ 371 Date: Aug. 1, 2017

(30) Foreign Application Priority Data
Feb. 18, 2015 (JP) 2015-029621

(51) Int. Cl. H05K 5/02; H05K 5/00

(52) U.S. Cl. CPC H05K 5/0217; H05K 5/0026; H05K 5/0247

(57) ABSTRACT

The present invention provides a case having a simple structure capable of suppressing the intrusion of water through a drainage channel. The case includes a first case body in which a channel that extends from a region serving as a first space is formed, and a second case body that is integrated with the first case body. A slit is formed in an outer wall portion of the second case body, and the channel formed in the first case body is continuous with at least a portion of the slit formed in the second case body. A lock piece portion for integration with the first case is formed on the outer wall portion of the second case body, and the lock piece portion has a cantilevered shape due to being defined by the slit.

### CROSS-REFERENCE TO RELATED APPLICATIONS

This application is the U.S. national stage of PCT/JP2016052408 filed Jan. 28, 2016, which claims priority of Japanese Patent Application 2015-029621 filed Feb. 18, 2015.

### TECHNICAL FIELD

The present invention relates to a case provided with a drainage channel.

### BACKGROUND

As disclosed in JP 2002-134939A noted below and the like, cases disposed in an environment that has large variations in temperature, such as a vehicle-mounted case for housing an electrical device, are sometimes provided with a channel for the drainage of water produced by the condensation of water vapor.

There are cases where the structure of the case becomes complex due to the provision of such a drainage channel. Also, this channel is open to the outside, thus leading to the risk of water intruding into the case through the channel.

A problem to be solved by the present invention is providing a case having a simple structure that enables suppressing the intrusion of water through the drainage channel.

### SUMMARY

A case according to the present invention for solving the aforementioned problem is a case in which a housed object is to be housed in a first space, the case including: a first case body in which a channel that extends from a region serving as the first space is formed; and a second case body that is integrated with the first case body, wherein a slit is formed in an outer wall portion of the second case body, and the channel formed in the first case body is continuous with at least a portion of the slit formed in the second case body.

A lock piece portion for integration with the first case may be formed on the outer wall portion of the second case body, the lock piece portion having a cantilevered shape due to being defined by the slit.

The channel may be continuous with a portion on a base end side of the slit that does not include an opening end edge.

A second space may be formed by the first case and the second case body, the second space being for housing at least a portion of a connection member for connection to the housed object housed in the first space.

The case may include a third case body that forms the first space by being integrated with the first case body, the channel formed in the first case body may have a first portion that extends from the first space and is covered by the third case body, and a second portion that extends from the first portion to at least a portion that is continuous with the slit, and is covered by the second case body.

An opening of the second space for passage of the connection member may be formed between the first case body and the second case body, and a projection portion that projects in a direction of reducing the size of the opening and is located outward of the second portion of the channel may be formed on the second case body.

### Advantageous Effects of Invention

With a case according to the present invention, integrating the first case body with the second case body obtains the state where the channel formed in the first case body is continuous with at least a portion of the slit formed in the second case body. In other words, in this structure, the channel formed in the first case body is not directly open to the outside, but rather is open to the outside via the slit formed in the second case body, thus making it difficult for water to intrude from the outside. Also, it is sufficient to merely form the slit in the second case body at a position continuous with (overlapped with) the channel formed in the first case body, thus making it possible to suppress increased complexity in the structure.

In the case of providing the lock piece portion for integrating the second case body with the first case body, a configuration is sufficient in which the slit is continuous with the channel. In other words, the slit formed in order to provide the lock piece portion that is capable of deforming can be used as an element that constitutes the drainage structure.

The channel is shaped so as to be continuous with a portion on the base end side of the slit that does not include the opening end edge, thus obtaining a structure in which the boundary between the first case body and the second case body is located at a position lower than the position where the channel and the slit are continuous, thereby obtaining a structure in which it is difficult for water to intrude through the boundary (gap) between the first case body and the second case body.

It is possible to obtain a structure in which the second space, which is for housing the connection member for connection to the housed object housed in the first space, is formed by the first case body and the second case body.

The channel includes the first portion that is covered by the third case body and the second portion that is covered by the second case body, and therefore it is possible to suppress the direct intrusion of water from the outside into the first portion that is near the housed object, while also ensuring the drainage effect realized by the second portion and the slit.

By providing the projection portion that projects in the direction of reducing the size of the opening of the second space for housing the connection member, and that is located outward of the second portion of the channel, it is possible to suppress the intrusion of water into the second space through this opening, and it is also possible to suppress the intrusion of water into the channel through the second space.

### BRIEF DESCRIPTION OF DRAWINGS

FIG. 1 is a diagram schematically showing the exterior of a case according to an embodiment of the present invention.

FIG. 2 is a diagram schematically showing the exterior of the case according to the present invention in a state where a second case body has been removed.

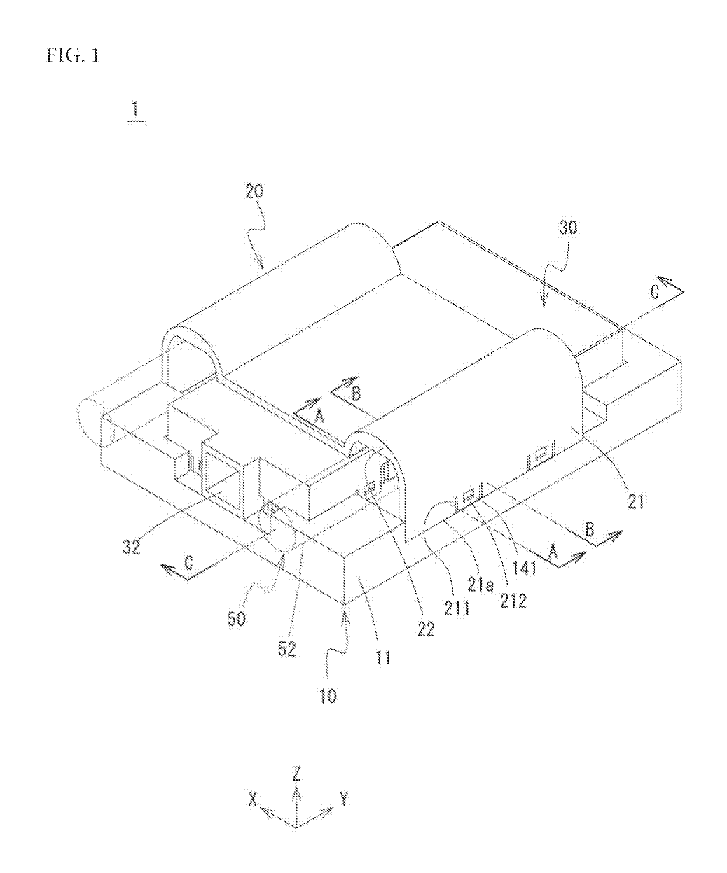

is a cross-sectional view taken along line A-A in FIG. 1 (connection member not shown).

is a cross-sectional view taken along line B-B in FIG. 1 (connection member not shown).

is a diagram schematically showing a cross-section taken along line C-C in FIG. 1.

is a side view of a case body according to the embodiment of the present invention, as viewed from the side on which a slit is formed.

is a diagram for describing a channel formed in a first case body (schematic view of a cross-section of the first case body taken along a plane that extends along the surface direction).

is an exterior view of a substrate unit that is one example of an object housed in the case body according to the embodiment of the present invention.

is a diagram showing an enlarged view of a portion on which an electronic component of the substrate unit (one of the terminals being for electrical connection to a conductive member) is mounted (showing the substrate and the conductive member fixed thereto).

is a cross-sectional view of the portion on which the electronic component of the substrate unit (one of the terminals being for electrical connection to the conductive member) is mounted (showing the substrate and the conductive member fixed thereto), and is taken along a plane that passes through a drain terminal and a source terminal.

### DETAILED DESCRIPTION OF PREFERRED EMBODIMENTS

Hereinafter, an embodiment of the present invention will be described in detail with reference to the drawings. Note that unless particularly specified otherwise, the height direction (up-down direction) in the following description refers to the direction along the Z axis shown in FIG. 1 and the like (the side in the direction of the arrowing being upward), and the surface direction refers to the direction along the XY plane. Note that these directions do not limit the installation direction of a case 1, and the case 1 according to the present embodiment is generally disposed such that a first case body is located on the lower side, and a second case body 20 is located on the upper side.

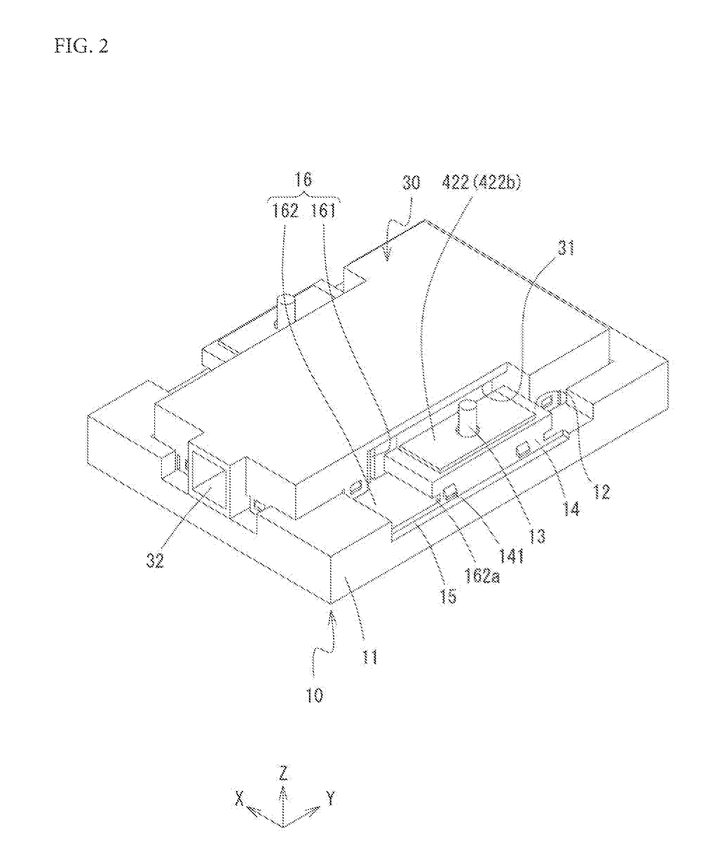

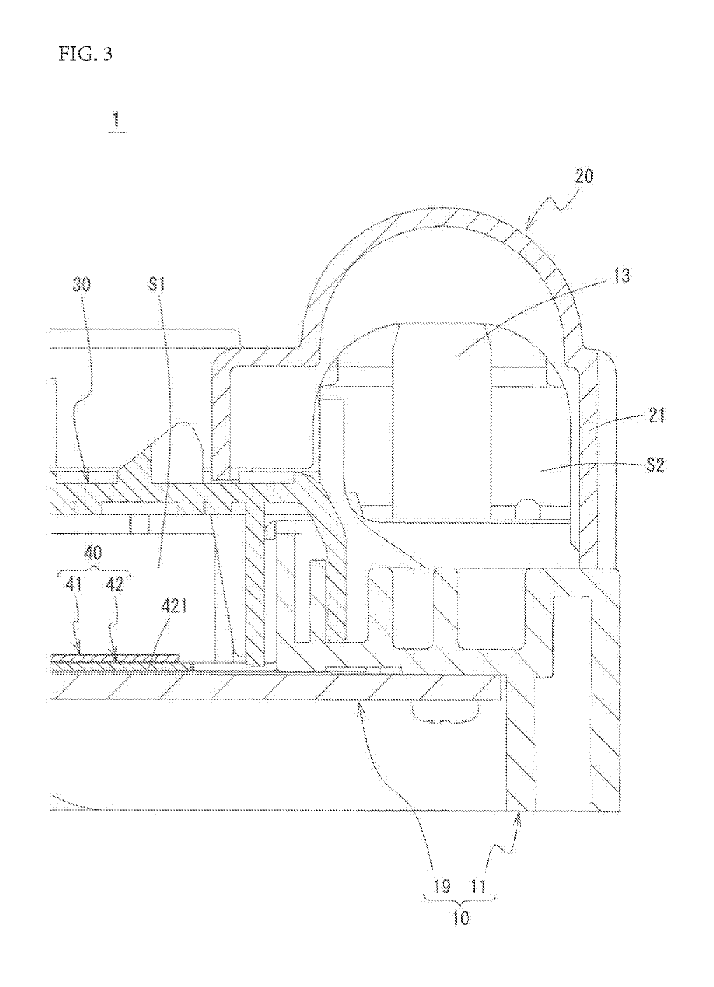

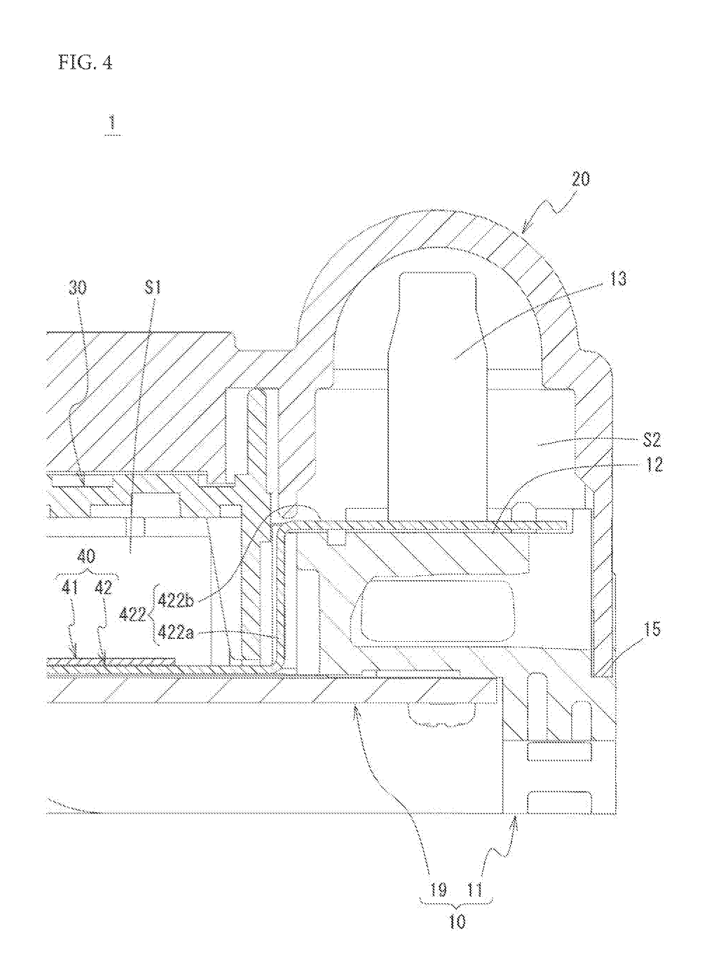

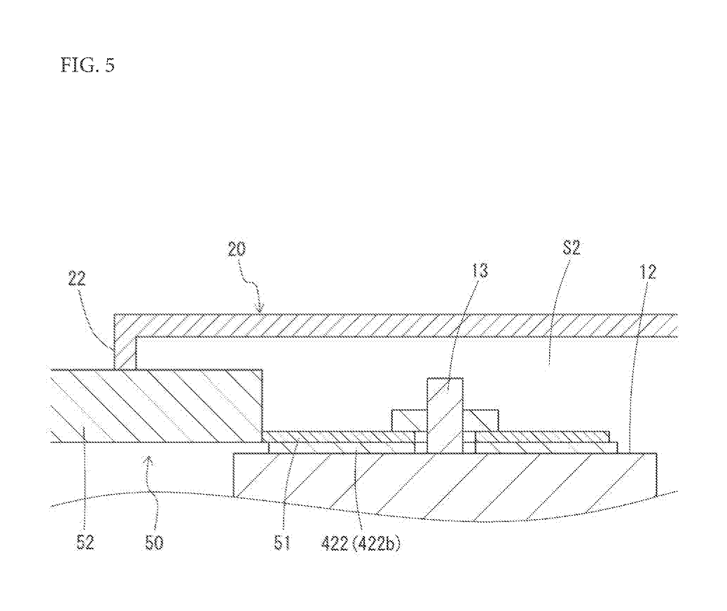

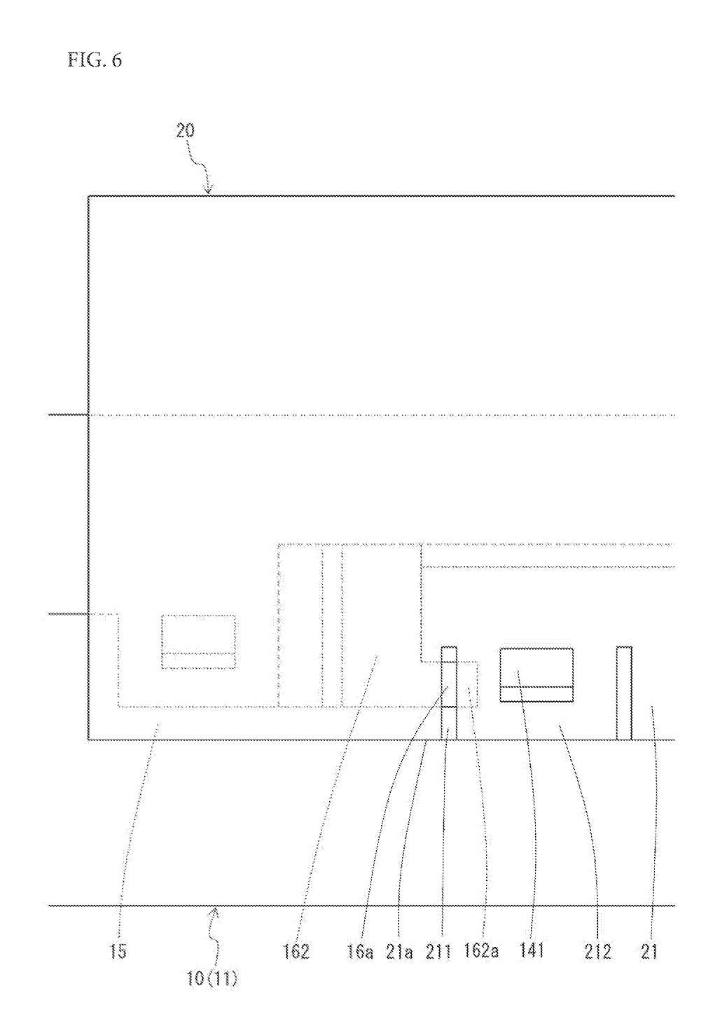

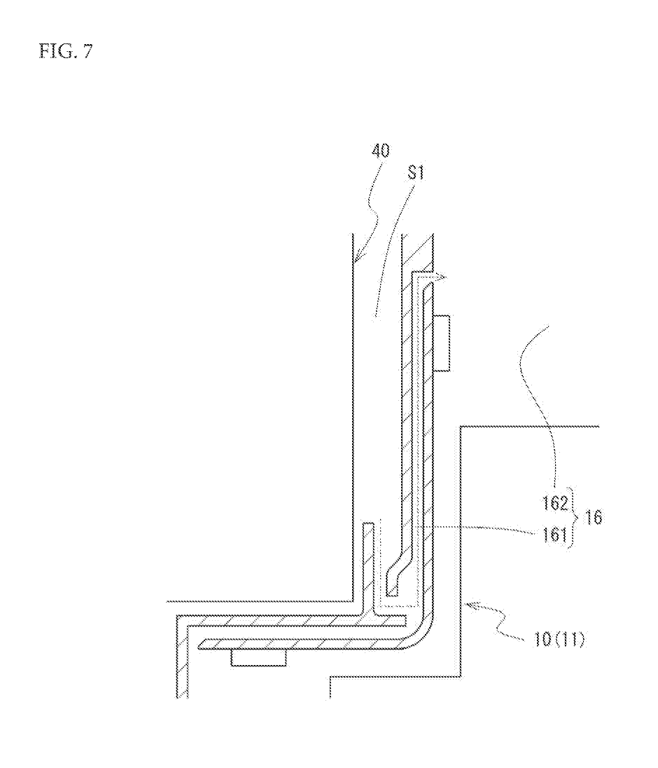

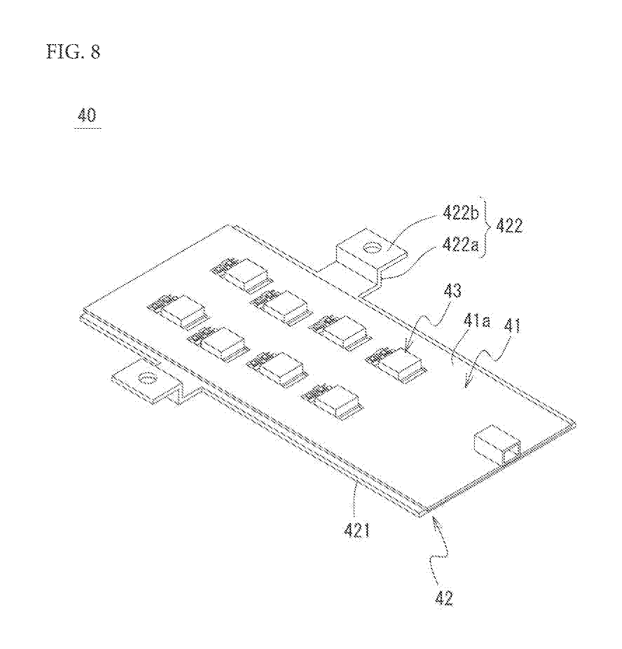

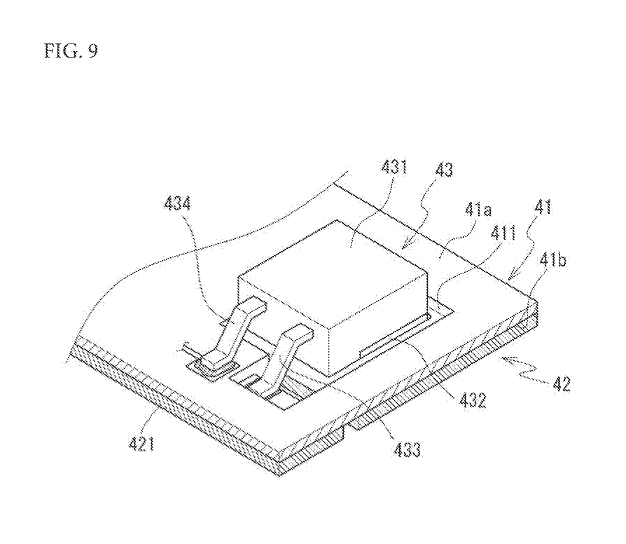

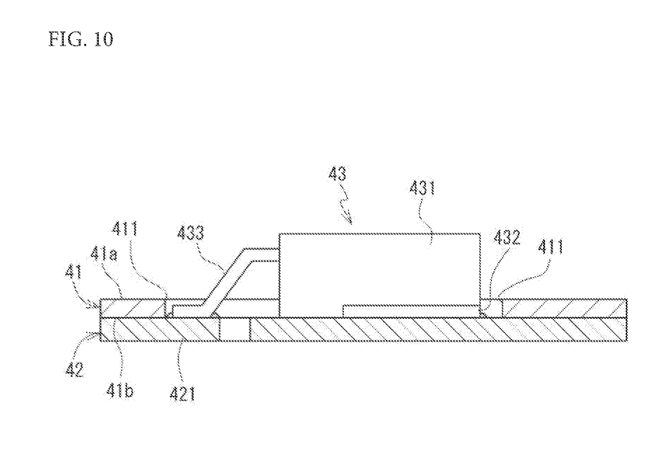

As shown in FIGS. 1 and 2, the case 1 according to an embodiment of the present invention is a case for housing a vehicle-mounted electrical device, and includes a first case body 10, a second case body 20, and a third case body 30. The object (electrical device) that is to be housed in the case 1 of the present embodiment is a substrate unit 40. A first space S1 for housing the housed object is formed in the first case body 10. The top of the first space S1 formed in the first case body 10 is covered by the third case body 30 (see FIGS. 3, 4, and the like). In other words, the first space S1 can also be said to be a space formed by the first case body 10 and the third case body 30. The first space S1 of the present embodiment is a space that is flat in the surface direction.

Also, connection members 50 (electrical wires 52 with terminals 51 in the present embodiment), which are for connection to the substrate unit 40 that is the housed object, are housed in the second case body 20. The bottoms of second spaces S2 formed in the second case body 20 are covered by the first case body 10. In other words, the second spaces S2 can also be said to be spaces formed by the first case body 10 and the second case body 20. The second spaces S2 are spaces in which openings for passage of the connection members 50 are formed.

In the present embodiment, the substrate unit 40 that is the housed object is housed in the first space S1. Note that although the substrate unit 40 and the connection members 50, which are for electrically connecting the substrate unit 40 to an external device, are illustrated using solid lines in the figures (excluding FIG. 1), the substrate unit 40 and the connection members 50 are not constituent elements of the case 1 according to the present embodiment. In other words, the substrate unit 40 is merely one example of an object to be housed in the case 1 according to the present embodiment. The substrate unit 40 has the following configuration.

The substrate unit 40 shown in FIGS. 8 to 10 includes a substrate 41 and a conductive member 42. The substrate 41 is obtained by forming a conductive pattern on one surface 41a (upper surface). The conduction path constituted by the conductive pattern is a conduction path for control (circuit part), and the current that flows through it is relatively smaller than the current that flows through the conduction path (circuit part) constituted by the conductive member 42.

The conductive member 42 has a main body portion 421 that is fixed to another surface 41b (lower surface) of the substrate 41, and extension portions 422 that extend from the main body portion 421. The conductive member 42 is formed with a predetermined shape by press processing or the like. The main body portion 421 of the conductive member 42 constitutes a power conduction path, which is a portion through which a relatively large current (larger than that which flows through the conduction path constituted by the conductive pattern) flows. Note that although the specific configurations of the conduction paths are not described here or illustrated, the main body portion 421 of the conductive member 42 has multiple portions that constitute the conduction path. These portions are each separated so as to not short circuit, and are integrated by being fixed to the substrate 41. These portions are connected by extra length portions before being fixed to the substrate 41, and are each separated from each other (prevented from being in direct contact) by cutting off the extra length portions after being fixed to the substrate 41. The conductive member 42 (main body portion 421) is also called a bus bar (bus bar plate) or the like. The main body portion 421 of the conductive member 42 is fixed to the other surface 41b of the substrate 41 via an insulating adhesive or bonding sheet, for example. The substrate 41 and the conductive member 42 are thus integrated.

The extension portions 422 of the conductive member 42 are portions formed so as to rise up from the main body portion 421. The extension portions 422 of the present embodiment each have a portion that extends upward from the main body portion 421 (base end portion 422a) and a portion that is bent from the leading end (upper end) of the base end portion 422a and extends along the surface direction (leading end portion 422b). The conductive member 42 of the present embodiment has multiple extension portions 422. The extension portions 422 are each integrated with any one of the separate main body portions 421 described above. In the present embodiment, one separated portion is connected to one extension portion 422. The leading end portions 422b of the extension portions 422 are portions for connection to the connection members 50 (input terminal portions or output terminal portions). The substrate unit 40 (conductive member 42) and an external device are electrically connected via these connection members 50.

Electronic components 43 each have an element main body 431 and terminal portions. The substrate unit 40 includes multiple electronic components 43. At least one terminal of a specific electronic component 43 is electrically connected to the main body portion 421 of the conductive member 42 via an opening 411 formed in the substrate 41. A transistor (FET) can be given as one example for the terminals among which at least one terminal is electrically connected to the main body portion 421 of the conductive member 42. A drain terminal 432 and a source terminal 433 of the transistor are connected to the main body portion 421 of the conductive member 42, and a gate terminal 434 is connected to the conductive pattern of the substrate 41. In this way, at least one terminal of at least one of the electronic components 43 is directly electrically connected to the conductive member 42. From another viewpoint, this means that there may be an electronic component 43 in which all of the terminals are directly electrically connected to the conductive pattern formed on the substrate 41 (in which at least one terminal is not directly electrically connected to the conductive member 42).

The substrate unit 40 configured in this way is housed in the first space S1 (see FIGS. 3, 4, and the like). Specifically, the portion of the substrate unit 40 other than the extension portions 422 is housed in the first space S1. In the present embodiment, the first case body 10 that forms the first space S1 includes a frame member 11 and a heat dissipation member 19. The frame member 11 has an approximately quadrangular shape, and the inward region serves as the first space S1. The heat dissipation member 19 is a flat plate-shaped member formed from a material that has high heat conductivity (copper or the like), and is fixed to the lower side of the frame member 11. The heat dissipation member 19 is fixed so as to cover the lower opening of the frame member 11. The flat first space S1 that expands in the surface direction is formed by the frame member 11 and the heat dissipation member 19. The frame member 11 can also be said to be the member that constitutes the side walls of the first space S1, and the heat dissipation member 19 can also be said to be the member that constitutes the bottom wall of the first space S1. At least a portion of the main body portion 421 of the conductive member 42 of the substrate unit 40 is bonded to the heat dissipation member 19. Accordingly, at least some of the heat generated by the substrate unit 40 is emitted to the outside via the heat dissipation member 19. Note that it is sufficient that the main body portion 421 of the conductive member 42 and the heat dissipation member 19 are bonded via an insulating material that has high heat conductivity.

The frame member 11 is provided with base portions 12 and male thread portions 13 that project upward from the base portions 12 (see FIG. 2 and the like). Through-holes through which the male thread portions 13 can pass are formed in the leading end portions 422b of the extension portions 422 of the conductive member 42. By inserting the male thread portions 13 into the through-holes formed in the leading end portions 422b, passing the male thread portions 13 through through-holes formed in terminals 51 of the connection members 50, and screwing nuts or the like onto the male thread portions 13, the leading end portions 422b and the terminals 51 are pressed against the base portions 12 and brought into close contact with each other. Accordingly, the conductive member 42 and the connection members 50 are put into an electrically connected state (see FIG. 5 and the like).

The opening of the first space S1 formed in the first case body 10 is covered by the third case body 30. In other words, it can also be said that the third case body 30 constitutes the upper wall of the first space S1. The third case body 30 is fixed to the frame member 11 of the first case body 10. The third case body 30 is shaped so as to cover at least a portion of the upper surface of the frame member 11, excluding the base portions 12. The outer walls of the third case body 30 are shaped so as to have cutouts in portions, and these cut-out portions (cutout portions 31) ensure gaps for the passage of the extension portions 422 even when the third case body 30 is fixed to the first case body 10 (see FIG. 2 and the like). Any structure for fixing the first case body 10 and the third case body 30 may be provided, and therefore will not be described here.

When the third case body 30 is fixed to the first case body 10, the aforementioned gaps are formed between the cutout portions of the third case body 30 and the first case body 10, and the extension portions 422 pass through these gaps. Accordingly, the leading end portions 422b of the extension portions 422 are located above the base portions 12. Note that the third case body 30 of the present embodiment is provided with a connector portion 32 for electrically connecting the substrate 41 to an external device.

The second case body 20 is fixed to the first case body 10 so as to cover the base portions 12. Along with the leading end portions 422b of the extension portions 422, at least a portion of each of the connection members 50 (terminals 51) is located above the base portion 12, and therefore both the leading end portions 422b and these portions are covered by the second case body 20. From another viewpoint, the leading end portions 422b of the extension portions 422 and at least a portion of each of the connection members 50 are housed in the second spaces S2 constituted by the second case body 20 and the first case body 10 (frame member 11).

The second spaces S2 are partially open spaces, and the connection members 50 (electrical wires 52) pass through these openings (see FIGS. 1, 5, and the like). The openings of the second spaces S2 can also be said to be gaps formed between the first case body 10 and the second case body 20. In the present embodiment, projection portions 22 are formed on the second case body 20. The projection portions 22 project in the direction of reducing the size of the openings of the second spaces S2 (downward in the present embodiment). It is sufficient that the projection portions 22 come into contact with the connection members 50 (electrical wires 52) by fixing the second case body 20 to the first case body 10 in the state where the connection members 50 are connected to the male thread portions 13 (see FIG. 5 and the like). Providing these projection portions 22 on the second case body 20 suppresses the intrusion of water through the openings of the second spaces S2.

The second case body 20 is provided with lock piece portions 212 for being fixing to the first case body 10. Specifically, outer wall portions 21 of the second case body 20 are each provided with slits 211 that extend in the up-down direction from the leading end, and the portions between these slits 211 are the lock piece portions 212. Due to the provision of the slits 211, the lock piece portions 212 are shaped as cantilever portions that are capable of deforming. Four of these lock piece portions 212 are provided in the second case body 20, and the first case body 10 and the second case body 20 are integrated (see FIGS. 1, 6, and the like) due to the lock piece portions 212 being locked to lock protrusions 141 provided on the first case body 10 (frame member 11). Specifically, when the second case body 20 is pressed against the first case body 10 from above, the lock piece portions 212 undergo elastic deformation, and the lock protrusions 141 are fitted into through-holes formed in the lock piece portions 212.

In this way, the substrate unit 40 (excluding portions of the extension portions 422) are housed in the first space S1, and portions of the extension portions 422 (leading end portions 422b) and portions of the connection members 50 (terminals 51) are housed in the second spaces S2. The case 1 according to the present embodiment is provided with a drainage structure for draining water in the first space S1 (water produced by the condensation of water vapor or the like, or water that entered from the outside) in which the substrate unit 40 is housed. The configuration of this drainage structure will be described below.

Channels 16 that extend from the first space S1 are formed in the first case body 10. Each channel 16 includes a first portion 161 that is covered by the third case body 30 and a second portion 162 that is covered by the second case body 20. As shown in FIG. 7, the first portion 161 is a portion that extends from the first space S1. In other words, one end of the first portion 161 is connected to the first space S1. The first portion 161 of the present embodiment is a groove that is open upward over its entirety. On the other hand, the second portion 162 is a portion that connects the first portion 161 to a later-described outlet 16a. The second portion 162 of the present embodiment is a space that is connected to the other end of the first portion 161, and is also connected to the outlet 16a. Note that the specific shape and the like of the channel 16 (first portion 161 and second portion 162) can be changed as appropriate. In other words, it may have any shape (is not necessarily required to be groove-shaped) as long as water can flow through it. As described above, the channel 16 of the present embodiment includes a portion that is on the upstream (first space S1) side and is covered by the third case body 30, and a portion that is on the downstream (outlet 16a) side and is covered by the second case body 20.

As described above, the second portion 162 is connected to the outlet 16a. In the present embodiment, the hole (space) that serves as the outlet 16a is formed in the second case body 20. Specifically, at least a portion of a slit 211 formed in the second case body 20 functions as the outlet 16a (see FIG. 6 and the like). In other words, a slit 211 that is formed for enabling deformation (cantilevering) of the lock piece portion 212 is used as the outlet 16a for drainage.

A step is formed in at least a portion of the outer edge of the frame member 11 that constitutes a portion of the first case body 10. Specifically, step portions 15 that recede so as to be lower than the portions in which the channels 16 (second portions 162) are provided (see FIG. 2 and the like) are formed. Also, support protrusions 14, which are protrusions that project upward, are formed on the frame member 11 that constitutes a portion of the first case body 10. The upper surfaces of the support protrusions 14 serve as the base portions 12. The lock protrusions 141 that project outward are formed on the outer faces of the support protrusions 14. The outer faces of the support protrusions 14 are planar (flush) with the surfaces of the step portions 15 that extend in the up-down direction. In a view from the side, grooves (transverse grooves 162a) are formed in the frame member 11 by removing portions of the base portions of the support protrusions 14 (see FIGS. 2, 6, and the like). The transverse grooves 162a are portions of the second portions 162.

When the inward surfaces of the outer wall portions 21 of the second case body 20 are pressed against the frame member 11 so as to oppose the outer faces of the support protrusions 14 and then the surfaces of the step portions 15 that extend in the up-down direction, the lock piece portions 212 formed on the outer wall portions 21 come into contact with the lock protrusions 141 and undergo elastic deformation. When the second case body 20 is then further pressed against the frame member 11, the lock piece portions 212 return to their original shape, and the lock protrusions 141 are fitted into the through-holes formed in the lock piece portions 212. Accordingly, the second case body 20 is fixed to the first case body 10 (frame member 11). In the state where the second case body 20 is fixed to the first case body 10, portions of the leading end sides of the outer wall portions 21 of the second case body 20 enter the step portions 15. In other words, the inward surfaces of portions of the leading end sides of the outer wall portions 21 of the second case body 20 are in close contact with the surfaces of the step portions 15 that extend in the up-down direction, and at least a portion of the leading ends (leading end edges 21a) of the outer wall portions 21 of the second case body 20 are located at a position lower than the portions where the second portions 162 of the channels 16 provided in the frame member 11 are continuous with the slits 211. More specifically, the leading end edges 21a of the portions where the slits 211 (lock piece portions 212) are formed in the outer wall portions 21 of the second case body 20 are located at a position lower than the portions where the second portions 162 of the channels 16 provided in the frame member 11 are continuous with the slits 211.

When the second case body 20 is fixed to the first case body 10, the second portions 162 of the channels 16 provided in the frame member 11 are continuous with slits 211 formed in the second case body 20. Specifically, in a view from the side, at least a portion of each of the transverse grooves 162a, which are portions of the second portions 162 of the channels 16, are overlapped with at least a portion of a slit 211. These overlapping portions serve as the outlets 16a of the channels 16. As described above, the leading ends (leading end edges 21a) of the outer wall portions 21 of the second case body 20 are located at positions lower than the channels 16 provided in the frame member 11. The slits 211 are formed so as to extend in the up-down direction from the leading ends of the outer wall portions 21 of the second case body 20, thus obtaining a structure in which portions of the upper sides of the slits 211 are overlapped with the second portions 162 (transverse grooves 162a) of the channels 16 (see FIG. 6 and the like).

As described above, in the case 1 according to the present embodiment, water that has entered the first space S1 that houses the substrate unit 40 can be drained to the outside through a channel 16 (first portion 161 and second portion 162) having one end connected to the first space S1 and having another end continuous with a slit 211 formed in the second case body 20. In other words, in this structure, the channel 16 formed in the first case body 10 is not directly open to the outside, but rather is open to the outside via a slit 211 formed in the second case body 20, thus making it difficult for water to intrude from the outside. Also, it is sufficient to merely form a slit 211 in the second case body 20 at a position continuous with (overlapped with) the channel 16 formed in the first case body 10, thus making it possible to suppress increased complexity in the structure.

Also, the slits 211 are formed in order to constitute the lock piece portions 212 for integrating the second case body 20 with the first case body 10 (in order to give the lock piece portions 212 a cantilevered shape capable of undergoing elastic deformation). In other words, the case 1 according to the present embodiment is superior in that the slits 211, which are formed in order to provide the lock piece portions 212 capable of undergoing elastic deformation, are used as elements constituting the drainage structure.

Also, at least a portion of each of the leading end edges 21a of the outer wall portions 21 of the second case body 20 is located at a position lower than the portion where a channel 16 formed in the first case body 10 is continuous with a slit 211. In other words, a portion of the upper side (base end side) of a slit 211 that does not include the opening end edge is overlapped with the second portion 162 (transverse groove 162a) of a channel 16, and the drainage outlet 16a is located at a position higher than the boundary between the outer wall surface of the second case body 20 and the outer wall surface of the first case body 10 (frame member 11) that constitutes a portion of the outer wall surface of the case 1 (see FIG. 6 and the like). More specifically, the lower-side portion of the slit 211 that is near the boundary between the outer wall surface of the second case body 20 and the outer wall surface of the first case body 10 (frame member 11) does not serve as the drainage outlet 16a. According to this configuration, it is possible to obtain a structure in which it is difficult for water to intrude through a gap between the first case body 10 and the second case body 20, while also ensuring the effect of drainage from the outlet 16a.

In particular, in the present embodiment, each channel 16 formed in the first case body 10 (frame member 11) includes the first portion 161 that is covered by the third case body 30 and the second portion 162 that is covered by the second case body 20. According to this configuration, it is possible to suppress the direct intrusion of water from the outside into the first portion 161 that is near the housed object, while also ensuring the drainage function achieved by the second portion 162 and the slit 211.

Also, the second case body 20 is provided with the projection portions 22 that project in the direction of reducing the size of the openings of the second spaces S2 in which the connection members 50 are housed, and that are located outward of the second portions 162 of the channels 16, thus making it possible to suppress the intrusion of water into the second spaces S2 through these openings, and also making it possible to suppress the intrusion of water into the channels 16 (second portions 162) through the second spaces S2.

Although an embodiment of the present invention is described in detail above, the present invention is not limited in any way to the foregoing embodiment, and various improvements can be made without departing from the gist of the present invention.

For example, although it is described that the case 1 according to the above embodiment is constituted by three case bodies, namely the first case body 10, the second case body 20, and the third case body 30, the number of case bodies, the specific shapes thereof, and the like can be changed as appropriate. It is sufficient to have a configuration in which a channel formed in one of the case bodies is in communication with a slit formed in another one of the case bodies, and in which at least a portion of this slit serves as a water drainage outlet. In this case as well, it is further preferable that the slit is for constituting a lock piece that is for integrating the case bodies with each other.

Also, although it is described that the case 1 according to the above embodiment is for housing the substrate unit 40, any object may be housed in the first space S1. Also, any object may be housed in the second spaces S2. The same technical idea is also applicable to a case where a space corresponding to the second spaces S2 is not provided.

1. A case in which a housed object is to be housed in a first space, the case comprising:
a first case body in which a channel that extends from a region serving as the first space is formed; and
a second case body that is integrated with the first case body,
wherein a slit is formed in an outer wall portion of the second case body, and
the channel formed in the first case body is continuous with at least a portion of the slit formed in the second case body.

2. The case according to claim 1, wherein a lock piece portion for integration with the first case body is formed on the outer wall portion of the second case body, the lock piece portion having a cantilevered shape due to being defined by the slit.

3. The case according to claim 1, wherein the channel is continuous with a portion on a base end side of the slit that does not include an opening end edge.

4. The case according to claim 1, wherein a second space is formed by the first case body and the second case body, the second space being for housing at least a portion of a connection member for connection to the housed object housed in the first space.

5. The case according to claim 1,
comprising a third case body that forms the first space by being integrated with the first case body,
wherein the channel formed in the first case body has
a first portion that extends from the first space and is covered by the third case body, and
a second portion that extends from the first portion to at least a portion that is continuous with the slit, and is covered by the second case body.

6. The case according to claim 5,
wherein an opening of the second space for passage of the connection member is formed between the first case body and the second case body, and
a projection portion that projects in a direction of reducing the size of the opening and is located outward of the second portion of the channel is formed on the second case body.

7. The case according to claim 2, wherein the channel is continuous with a portion on a base end side of the slit that does not include an opening end edge.

8. The case according to claim 2, wherein a second space is formed by the first case body and the second case body, the second space being for housing at least a portion of a connection member for connection to the housed object housed in the first space.

9. The case according to claim 3, wherein a second space is formed by the first case body and the second case body, the second space being for housing at least a portion of a connection member for connection to the housed object housed in the first space.

10. The case according to claim 2,
comprising a third case body that forms the first space by being integrated with the first case body,
wherein the channel formed in the first case body has
a first portion that extends from the first space and is covered by the third case body, and
a second portion that extends from the first portion to at least a portion that is continuous with the slit, and is covered by the second case body.

11. The case according to claim 3,
comprising a third case body that forms the first space by being integrated with the first case body,
wherein the channel formed in the first case body has
a first portion that extends from the first space and is covered by the third case body, and
a second portion that extends from the first portion to at least a portion that is continuous with the slit, and is covered by the second case body.

12. The case according to claim 4,
comprising a third case body that forms the first space by being integrated with the first case body,
wherein the channel formed in the first case body has
a first portion that extends from the first space and is covered by the third case body, and
a second portion that extends from the first portion to at least a portion that is continuous with the slit, and is covered by the second case body.
